(19) United States
(12) Patent Application Publication
(10) Pub. No.: US 2026/0328836 A1
(43) Pub. Date: Oct. 22, 2026

(54) DIAGNOSIS DEVICE, DIAGNOSIS SYSTEM, AND DIAGNOSIS METHOD FOR PROCESSING APPARATUS

(71) Applicant: HITACHI HIGH-TECH CORPORATION, Minato-ku, Tokyo (JP)

(72) Inventor: Shota UMEDA

(21) Appl. No.: 19/103,442

(22) PCT Filed: Sep. 15, 2023
(86) PCT No.: PCT/JP2023/033673

§ 371 Date: Feb. 12, 2025

(51) Int. Cl. G01R 31/28

(52) U.S. Cl. CPC G01R 31/2831

(57) ABSTRACT

A diagnosis device and method for preventing a false alarm occurring in a component whose state is measured by a plurality of sensors or in each component in a processing apparatus group during deterioration diagnosis for a processing apparatus, and enabling efficient countermeasures. Therefore, a diagnosis device for a processing apparatus according to the invention is a device using a component in the processing apparatus as a maintenance target, and includes: a feature change calculation unit configured to calculate a deterioration degree corresponding to a change index based on a feature of each piece of sensor waveform data of a sensor item corresponding to a plurality of sensors (state sensor group) that measure a state of the component; and a component deterioration degree calculation unit configured to calculate a component deterioration degree corresponding to the component in a one-to-one manner using a plurality of the deterioration degrees.

### TECHNICAL FIELD

The present invention relates to a diagnosis device, a diagnosis system, and a diagnosis method for a processing apparatus for processing a semiconductor wafer.

### BACKGROUND ART

A processing apparatus is an apparatus for performing a processing for forming a fine shape on a semiconductor wafer. In the processing apparatus, normally, maintenance work such as cleaning and replacement of a component as a maintenance target is periodically performed based on the number of wafers to be treated or the like. However, unplanned maintenance work may occur due to deterioration of components caused by accumulation of reaction by-products or the like according to aging or usage methods. In order to reduce a non-operation time due to unplanned maintenance, it is required to sequentially monitor deterioration states of the components and take early countermeasures such as cleaning and component replacement according to the deterioration states.

In order to implement such early countermeasures, in a diagnosis device for the processing apparatus, first, a feature indicating a sensor waveform data feature is calculated using sensor waveform data which is a time-series signal including a plurality of sensor items sequentially acquired for each processing from a plurality of state sensors added to components in the processing apparatus (a data item of the sensor waveform data is referred to as a sensor item). Further, a deterioration degree indicating a deterioration state of a component is estimated from a deviation from a value at a normal time based on the feature, and is compared with a preset alarm issuance threshold to determine whether maintenance is necessary, and alarm issuance is performed.

In relation to the diagnosis for the processing apparatus, for example, WO2018/061842 (PTL 1) discloses that “An abnormality detection device estimates a state where noise is removed from a summary value in which observed values are collected by applying statistical modeling to the summary value, and generates a predicted value obtained by predicting a summary value of a previous period based on the estimation. The abnormality detection device detects the presence or absence of an abnormality in a monitoring target device based on the predicted value.” JP2012-9064A (PTL 2) discloses “a learning-type process abnormality diagnosis device implementing accurate abnormality detection and abnormality diagnosis performance suitable for actual process monitoring”. These related techniques are a so-called individual approach in which each piece of sensor waveform data is subjected to statistical processing individually and deterioration estimation is performed by comparing a predicted value with a current value.

### CITATION LIST

### Patent Literature

PTL 1: WO2018/061842

PTL 2: JP2012-9064A

### SUMMARY OF INVENTION

### Technical Problem

However, in the diagnosis for the processing apparatus, it is considered that a false alarm occurs in relation to the deterioration diagnosis due to the following causes in the related art, and it is difficult to efficiently take countermeasures based on the diagnosis result.

First, in the processing apparatus, since the states of the components in the apparatus also change according to a processing history, the false alarm may occur due to an initial state difference between the components in a processing apparatus group. In the diagnosis using the individual approach as in PTLs 1 and 2, there is originally no problem recognition corresponding to a variation among the components in the process apparatus group.

Second, the false alarm may occur due to a setting of an alarm issuance threshold. In a case of setting the threshold based on past knowledge of an operator, the occurrence of the false alarm depends on an experience value of the operator. In addition, the threshold may be set by providing a management criterion such as 3σ for a variation in features of sensors in each processing apparatus in a normal state. In this case, the processing apparatus is provided with various sensors, and the sensors interfere with each other under the control or are influenced by the state of the apparatus, so that it is rare that outputs of all the sensor items are stabilized. Therefore, in a case of diagnosing a deviation from the normal state for various sensor items, the false alarms may frequently occur. In a case of setting the threshold based on a sensor value generated during a deterioration event, a frequency of the deterioration event is relatively low, and thus a setting itself is difficult. In the diagnosis using the individual approach as in PTLs 1 and 2, there is no problem recognition related to the threshold setting of the deterioration state corresponding to a difference in apparatus or various sensor items.

Third, since the plurality of sensors added to the components in the processing apparatus interfere with each other, in a method of performing diagnosis based on the feature calculated for each sensor as in the individual approach as in PTLs 1 and 2, the diagnosis result for each sensor may not be directly connected to the deterioration state of the component, and may lead to the false alarm.

Therefore, an object of the invention is to provide a technique capable of preventing a false alarm occurring in a component whose state is measured by a plurality of sensors or in each component in a processing apparatus group during deterioration diagnosis for a processing apparatus, and enabling efficient countermeasures.

### Solution to Problem

In order to solve the above problems, one representative diagnosis device for a processing apparatus according to the invention is a diagnosis device for a processing apparatus that uses a component in the processing apparatus as a maintenance target. The diagnosis device includes: a feature change calculation unit configured to calculate a deterioration degree corresponding to a change index based on a feature of each piece of sensor waveform data of a sensor item corresponding to a plurality of sensors (state sensor group) that measure a state of the component; and a component deterioration degree calculation unit configured to calculate a component deterioration degree corresponding to the component in a one-to-one manner using a plurality of the deterioration degrees.

### Advantageous Effects of Invention

According to the invention, it is possible to provide a technique capable of preventing a false alarm occurring in a component whose state is measured by a plurality of sensors or in each component in a processing apparatus group during deterioration diagnosis for a processing apparatus, and enabling efficient countermeasures.

Problems, configurations, and effects other than those described above will be clarified by the following description of embodiments.

### BRIEF DESCRIPTION OF DRAWINGS

FIG. 1 is an overall configuration diagram of processing apparatuses and a diagnosis device for the processing apparatuses.

FIG. 2 is a relationship diagram showing positioning of component deterioration degrees and an apparatus common threshold, or the like.

FIG. 3 is a flowchart showing an example of a flow of processing in a computer 30.

FIG. 4 is a flowchart showing an example of a flow of processing in a server 50.

FIG. 5 is a diagram illustrating an example of an apparatus common threshold setting method.

FIG. 6 is a diagram showing an example of a display screen in a diagnosis result display unit 512.

### DESCRIPTION OF EMBODIMENTS

Hereinafter, an embodiment of the invention will b described with reference to the drawings. In the drawings illustrating the embodiment, the same parts are denoted by the same reference signs in principle, and the repeated description thereof is omitted.

### Processing Apparatus

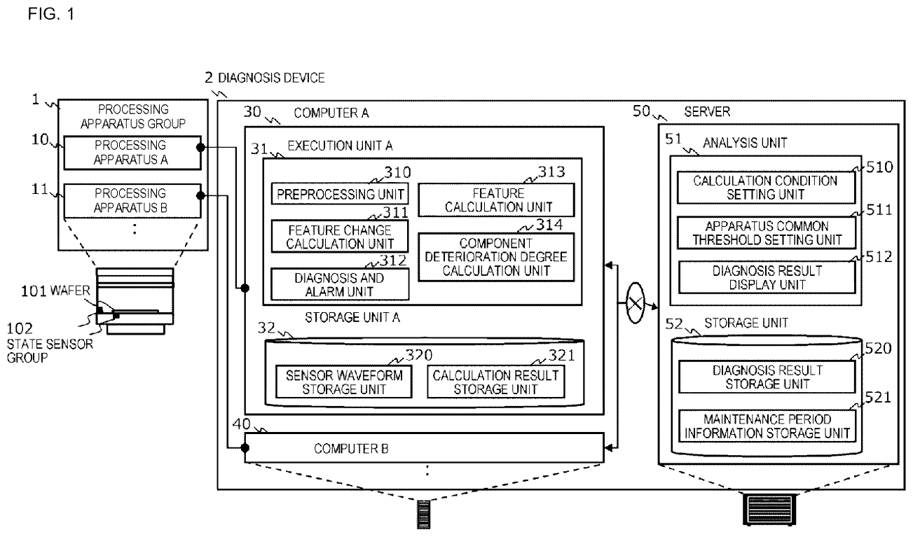

FIG. 1 is an overall configuration diagram of processing apparatuses and a diagnosis device for the processing apparatuses. As shown in FIG. 1, a processing apparatus A (10), a processing apparatus B (11), and the like constituting a processing apparatus group 1 according to the present embodiment process a wafer (sample 101) under preset processing conditions. In addition, each processing apparatus is provided with components having a same type, a state sensor group 102 including a plurality of sensors for measuring a state of the component is added to each component, and measurement values of sensor values (for example, temperature or pressure) during processing or during idling can be acquired as sensor waveform data. Examples of the processing apparatus, the component, and the state sensor include a plasma processing apparatus, a microwave generation unit, and a current and voltage sensor, respectively.

### Diagnosis Device

As shown in FIG. 1, a diagnosis device 2 includes a computer group (computer 30, computer 40, and the like) including an execution unit 31 that acquires the sensor waveform data corresponding to each processing apparatus in the processing apparatus group 1 and that executes calculation and a storage unit 32 that stores information necessary for processing of the execution unit. The diagnosis device 2 further includes a server 50 including an analysis unit 51 that sets calculation conditions of the execution unit 31 and an apparatus common threshold and that displays a diagnosis result and including a storage unit 52 that stores information necessary for processing of the analysis unit 51.

The processing apparatus group 1 is connected to the computer group (computer 30, computer 40, and the like) directly or via a network. The computer group (computer 30, computer 40, and the like) and the server 50 are connected to each other via a network. Accordingly, each computer can perform calculation by the execution unit 31 using the sensor waveform data acquired from each processing apparatus at a high speed. In addition, the server 50 can set the calculation conditions and the threshold in the processing apparatus group 1 and can analyze and display the diagnosis result. However, the connection between the computer group and the server 50 is not necessarily limited to the network, and may be direct connection in the processing apparatus.

### Computer

The execution unit 31 is implemented by a processor such as a CPU or a GPU, and includes a preprocessing unit 310, a feature change calculation unit 311, a diagnosis and alarm unit 312, a feature calculation unit 313, and a component deterioration degree calculation unit 314 to be described later.

The storage unit 32 is implemented by a memory, a hard disk, and the like, and includes a sensor waveform storage unit 320 and a calculation result storage unit 321 to be described later.

### Server

The analysis unit 51 is implemented by a processor such as a CPU or a GPU, and includes a calculation condition setting unit 510, an apparatus common threshold setting unit 511, and a diagnosis result display unit 512 to be described later.

The storage unit 52 is implemented by a memory, a hard disk, and the like, and includes a diagnosis result storage unit 520 and a maintenance period information storage unit 521 to be described later.

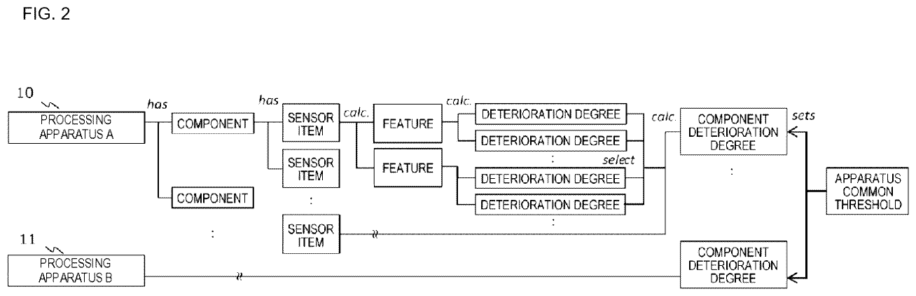

FIG. 2 is a relationship diagram showing positioning of component deterioration degrees and an apparatus common threshold, or the like. The processing apparatus includes one or more components, and a plurality of sensors (state sensor group) are added to each component. Then, one or more features are calculated for a sensor item of each sensor, and one or more deterioration degrees are calculated for each feature. In this manner, from a plurality of deterioration degrees obtained from one component, a component deterioration degree corresponding to the component in a one-to-one manner is obtained by calculation.

Further, the apparatus common threshold serving as a reference for deterioration detection is set based on the component deterioration degree for the same type of components provided in the plurality of processing apparatuses (processing apparatus group).

### Processing in Computer

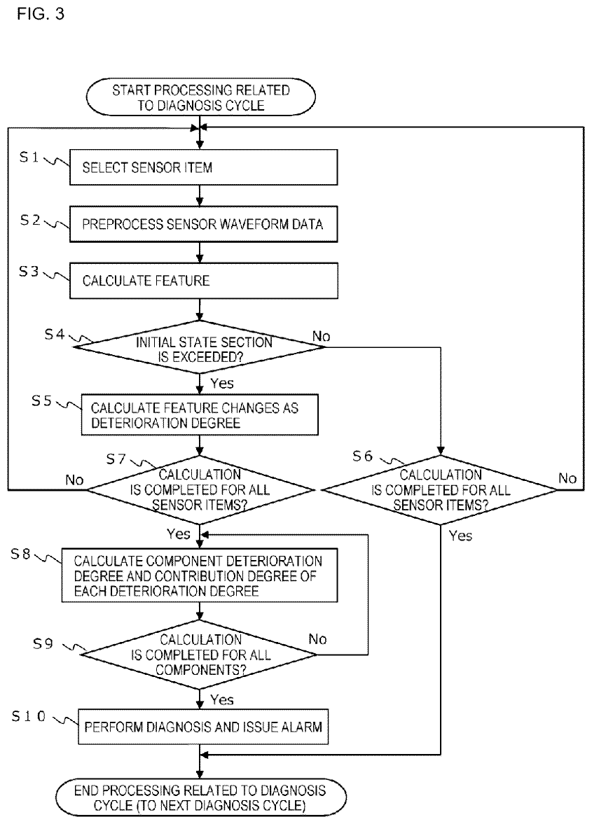

An example of diagnosis of a deterioration state for each component in the processing apparatus 10 performed by the computer 30 will be described. FIG. 3 is a flowchart showing an example of a flow of processing in the computer 30. FIG. 3 shows a flow of processing for each diagnosis cycle. The diagnosis cycle may be, for example, for each process or may be set at a regular time interval.

First, the computer 30 acquires sensor waveform data in a diagnosis cycle from the sensor waveform storage unit 320. The sensor waveform data is configured such that sensor values are stored in time series, such as a processing time and time point, for a plurality of sensor items, respectively. Here, the preprocessing unit 310 selects one sensor item in the sensor waveform data (S1).

Next, the preprocessing unit 310 performs preprocessing on the sensor waveform data including the selected sensor item (S2). A preprocessing method is optional, and for example, a process ID which is information for identifying a process condition is used to designate a process ID used for diagnosis, and the sensor waveform data associated with the process ID is extracted. Further, extraction of a processing time section used for diagnosis, removal of a missing value for facilitating handling of data, and standardization are performed.

Next, the feature calculation unit 313 calculates a feature indicating a feature of the sensor waveform data using the preprocessed sensor waveform data (S3). As shown in FIG. 2, one or more features are calculated for each sensor item. As the feature, for example, a statistic amount such as a mean average value or a standard deviation of the sensor waveform data can be used. For example, in a plasma processing apparatus, an average value or the like in a specific time section with respect to waveform data of a current value may be used as the feature. A feature having a high probability to be related to deterioration may be calculated by collating with domain knowledge of the component, or a plurality of features may be calculated.

Subsequently, feature change calculation unit 311 determines whether an initial state section is exceeded (S4). An initial state section refers to a time interval from immediately after maintenance work of the component to a certain period.

When the initial state section is not exceeded in the diagnosis cycle at a determination time point, the preprocessing unit 310 determines whether the calculation of the feature is completed for all sensor items as feature calculation targets (S6), and when the calculation is completed, the processing in the diagnosis cycle ends. In S6, if the calculation is not completed, the processing proceeds to select another sensor item and continues.

In S4, when the initial state section is exceeded, the feature change calculation unit 311 calculates a deterioration degree by taking a change amount from an initial state for each calculated feature (S5). For each feature, the deterioration degree is calculated using a plurality of change indices. Examples of the change index include a difference or a ratio between a mean value of features in the initial state section and the feature in the diagnosis cycle, and a Mahalanobis distance between the feature in the initial state section and the feature in the diagnosis cycle. In this way, in each processing apparatus of the processing apparatus group 1, the deterioration degree is defined based on the change amount from the initial state, thereby making it possible to compare the deterioration degree between the processing apparatuses. In addition, since a change index to be compared depends on the sensor item, a plurality of change indices are defined, and a plurality of deterioration degrees are calculated based on the plurality of change indices. For example, if the change amount from the initial state is a significant physical quantity, the difference is assumed to be effective as the change index, and if a change rate is a significant physical quantity, the ratio is assumed to be effective as the change index. In addition, even in the initial state, if the feature has a large variation, the Mahalanobis distance considering the variation is assumed to be effective.

Subsequently, the component deterioration degree calculation unit 314 determines whether the calculation of the deterioration degree is completed for all the sensor items (S7). When the calculation is not completed, the same process is repeated for another sensor item, and when the calculation is completed, the process proceeds to S8.

In S8, the component deterioration degree calculation unit 314 calculates an integrated index as a component deterioration degree using a plurality of deterioration degrees calculated for each component. A contribution degree of each deterioration degree to the component deterioration degree is also collectively calculated. Since the calculation condition of the component deterioration degree is calculated in the calculation condition setting unit 510, an example of a calculation method will be described later. The component deterioration in the processing apparatus is assumed to be caused by overlapping of a plurality of deterioration factors, or even when there is a single deterioration factor, the deterioration state is assumed to influence a plurality of sensor items. By a comprehensive approach using the component deterioration degree calculated based on individual deterioration degrees, it is possible to calculate the deterioration degree in consideration of interactions among the plurality of sensor items and to enable the diagnosis.

Subsequently, the diagnosis and alarm unit 312 determines whether the calculation is completed for all components to be diagnosed in the calculation of the component deterioration degree, and repeats the calculation until the calculation is completed for all the components (S9).

Finally, the diagnosis and alarm unit 312 compares the apparatus common threshold set in advance for each component by the apparatus common threshold setting unit 511 with a value obtained by calculating the component deterioration degree in the diagnosis cycle, and notifies the server 50 of alarm issuance when the apparatus common threshold is exceeded (S10). A series of calculation results calculated by the computer 30 are stored in the calculation result storage unit 321.

### Processing in Server

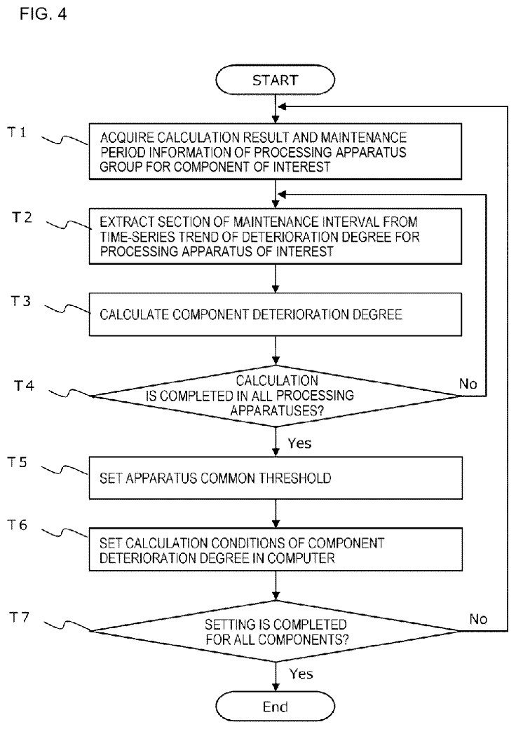

An example of processing performed by the server 50 to set the calculation conditions and the apparatus common threshold in the computer 30 will be described. FIG. 4 is a flowchart showing an example of a flow of the processing in the server 50. The processing flow related to the setting of the calculation conditions and the apparatus common threshold may be performed at a timing when it is necessary to set and update new calculation conditions and values of the apparatus common threshold.

First, the calculation condition setting unit 510 acquires the calculation result of the deterioration degree and the maintenance period information in the processing apparatus group 1 for a component of interest from the calculation result storage unit 321 and the maintenance period information storage unit 521, respectively (T1). The maintenance period information includes history information such as a period and contents of maintenance performed due to deterioration of components in each processing apparatus.

Next, the calculation condition setting unit 510 extracts the deterioration degree in a section of a maintenance interval based on the maintenance period information from a time-series trend of the deterioration degree calculated in each diagnosis cycle in the computer 30 for the processing apparatus of interest (T2). Accordingly, a left end of the time-series trend of the deterioration degree is the initial state, and a right end thereof indicates the deterioration state. Since the computer 30 calculates a plurality of deterioration degrees, there are also a plurality of time-series trends of the deterioration degrees. For a processing apparatus not including the maintenance period information, that is, a new processing apparatus or a processing apparatus that is in use after the maintenance (in which a deterioration event does not occur), a deterioration degree trend from the initial state to the latest calculation time point is extracted. Since the occurrence of the deterioration event is relatively rare, it is effective to prevent a false alarm by utilizing data of the processing apparatus not including the maintenance period information.

Next, in the calculation condition setting unit 510, the component deterioration degree is calculated using the time-series trend of the plurality of deterioration degrees (T3). There are various methods for calculating the component deterioration degree, for example, a model for calculating the component deterioration degree can be constructed by applying a machine learning method including a decision tree structure. When constructing the model, a model in which each deterioration degree trend is used as an explanatory variable and a deterioration period is used as an objective variable is used, and parameters of the model are optimized according to data. From the viewpoint of narrowing down the effective feature for each sensor item, a machine learning method having a feature selection function may be used to select one deterioration degree for each sensor item and then calculate the component deterioration degree, as shown in FIG. 2. Further, from the viewpoint of the description of the diagnosis result, it is desirable to use a model capable of collectively calculating the contribution degree of each deterioration degree to the component deterioration degree. A plurality of models may be constructed.

In the apparatus common threshold setting unit 511, whether the calculation is completed for all processing apparatuses to be diagnosed is determined, the processing from T2 to T3 is repeated for the processing apparatuses, and the component deterioration degree of a component of interest is calculated (T4).

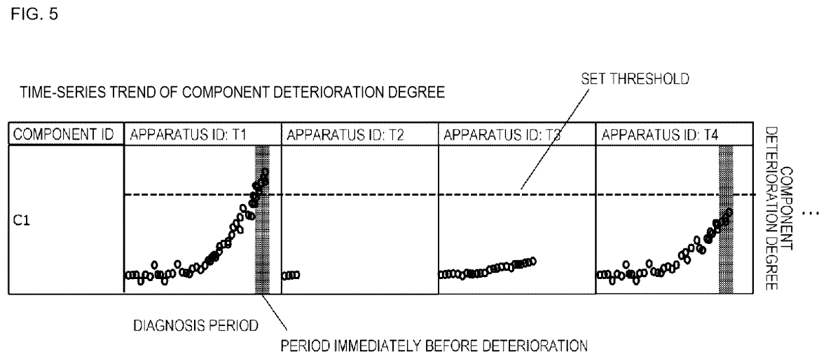

Next, the apparatus common threshold setting unit 511 sets a threshold common to the processing apparatus group 1 for each component deterioration degree (T5). FIG. 5 is a diagram illustrating an example of an apparatus common threshold setting method. FIG. 5 shows a state where the time-series trend of the component deterioration degree is calculated in the processing apparatus group 1. Set thresholds are comprehensively scanned, and a threshold common to the apparatuses is set such that a prediction accuracy index in a desired deterioration period becomes maximum. In order to prevent the false alarm, for example, a recall under a condition in which a precision is equal to or greater than a reference value is used as the prediction accuracy index. In a case of constructing a plurality of component deterioration degree calculation models in T3, a component deterioration degree calculation model used for diagnosis in the computer 30 is selected based on the prediction accuracy index. In this manner, it is possible to prevent the false alarm caused by an individual factor of the apparatus by the comprehensive approach of setting the apparatus common threshold so as to optimize the prediction accuracy index.

Finally, the calculation condition setting unit 510 sets the selected component deterioration degree calculation model (calculation condition) and apparatus common threshold as conditions used for diagnosis in the computer 30 (T6).

Subsequently, the calculation condition setting unit 510 determines whether the setting is completed for all the components to be diagnosed, repeats the processing from T1 to T6 (T7), and ends the processing.

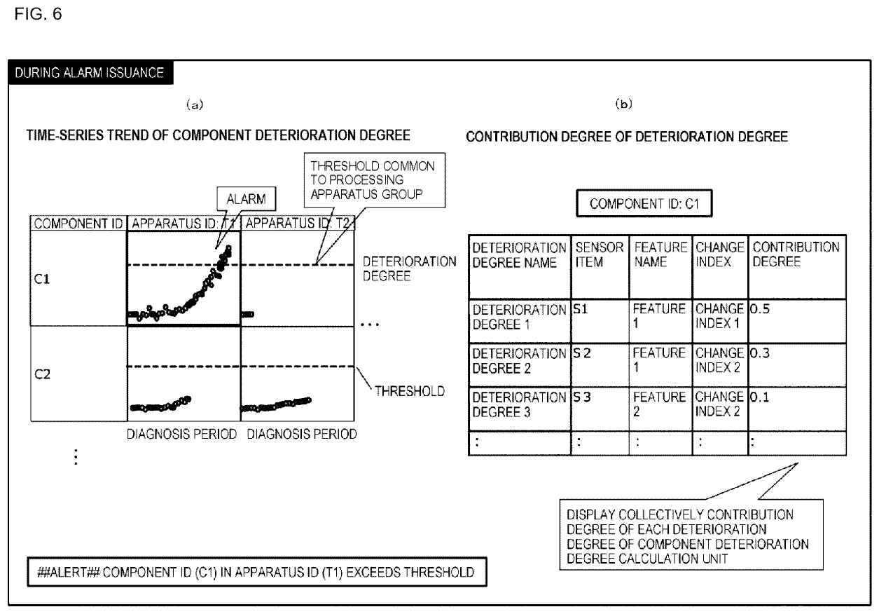

FIG. 6 is a diagram showing an example of a display screen in the diagnosis result display unit 512. As shown in (a) of FIG. 6, the time-series trend of the component deterioration degree and the apparatus common threshold can be listed for all the components to be diagnosed in the processing apparatus group 1. Accordingly, it is possible to grasp at a glance which component in which processing apparatus is close to the deterioration state. In addition, when an error occurs in a processing apparatus whose cause is temporarily unknown, it is possible to take an efficient countermeasure by preferentially setting a component having a state close to a deterioration state as a maintenance work target.

Further, as shown in (b) of FIG. 6, by designating the component ID, the contribution degree of each deterioration degree (deterioration degree calculation condition) to the component deterioration degree can be checked. This serves as auxiliary information for cause estimation by collating with the domain knowledge of the component, thereby enabling efficient countermeasures.

Although the embodiment is described in detail above, the invention is not limited to the above embodiment, and various modifications can be made without departing from the gist thereof. For example, when it is difficult to provide the server 50, the computer 30 may be configured to perform a part of the processing of the server 50.

Aspects that may be contents of the invention will be described below, and the invention is not limited thereto.

### (Aspect 1)

A diagnosis device for a processing apparatus that uses a component in the processing apparatus as a maintenance target, the diagnosis device including:
a feature change calculation unit configured to calculate a deterioration degree corresponding to a change index based on a feature of each piece of sensor waveform data of a sensor item corresponding to a plurality of sensors (state sensor group) that measure a state of the component; and
a component deterioration degree calculation unit configured to calculate a component deterioration degree corresponding to the component in a one-to-one manner using a plurality of the deterioration degrees.

### (Aspect 2)

The diagnosis device for a processing apparatus according to Aspect 1, further including: a diagnosis and alarm unit configured to perform diagnosis and issue an alarm by comparing an apparatus common threshold set among components in a processing apparatus group with the component deterioration degree.

### (Aspect 3)

The diagnosis device for a processing apparatus according to Aspect 1 or 2, in which the feature change calculation unit uses, as the change index, at least one of a difference between the feature in a diagnosis cycle and a mean value of features in an initial state section (hereinafter referred to as “initial features”) of the component, a ratio of the feature to the mean value of the initial features, or a Mahalanobis distance between the feature and the mean value of the initial features.

### (Aspect 4)

The diagnosis device for a processing apparatus according to any one of Aspects 1 to 3, in which the component deterioration degree calculation unit calculates the component deterioration degree as a continuous probability value by using a method of applying a regression model including a decision tree structure.

### (Aspect 5)

The diagnosis device for a processing apparatus according to Aspect 2, further including: an apparatus common threshold setting unit configured to set the apparatus common threshold by comprehensively searching a time-series trend of the component deterioration degree in each component of the processing apparatus group for a prediction accuracy index in a deterioration period.

### (Aspect 6)

The diagnosis device for a processing apparatus according to Aspect 5, in which the apparatus common threshold setting unit sets the apparatus common threshold using a precision and a recall as the prediction accuracy index such that the precision is equal to or greater than a reference value and the recall is maximum.

### (Aspect 7)

The diagnosis device for a processing apparatus according to any one of Aspects 2, 5, and 6, further including: a diagnosis result display unit configured to collectively display a time-series trend of the component deterioration degree in each component of the processing apparatus group and contribution degrees of the plurality of deterioration degrees used for calculating the component deterioration degree.

### (Aspect 8)

A diagnosis system for a processing apparatus that uses a component in the processing apparatus as a maintenance target, the diagnosis system including:
a feature change calculation unit configured to calculate a deterioration degree corresponding to a change index based on a feature of each piece of sensor waveform data of a sensor item corresponding to a plurality of sensors (state sensor group) that measure a state of the component; and
a component deterioration degree calculation unit configured to calculate a component deterioration degree corresponding to the component in a one-to-one manner using a plurality of the deterioration degrees.

### (Aspect 9)

The diagnosis system for a processing apparatus according to Aspect 8, further including: a diagnosis and alarm unit configured to perform diagnosis and issue an alarm by comparing an apparatus common threshold set among components in a processing apparatus group with the component deterioration degree.

### (Aspect 10)

A diagnosis method for a processing apparatus that uses a component in the processing apparatus as a maintenance target, the diagnosis method including:
a step of calculating, by a feature change calculation unit, a deterioration degree corresponding to a change index based on a feature of each piece of sensor waveform data of a sensor item corresponding to a plurality of sensors (state sensor group) that measure a state of the component; and
a step of calculating, by a component deterioration degree calculation unit, a component deterioration degree corresponding to the component in a one-to-one manner using a plurality of the deterioration degrees.

### (Aspect 11)

The diagnosis method for a processing apparatus according to Aspect 10, further including: a step of performing diagnosis and issuing an alarm, by a diagnosis and alarm unit, by comparing an apparatus common threshold set among components in a processing apparatus group with the component deterioration degree.

### REFERENCE SIGNS LIST

1: processing apparatus group
2: diagnosis device
10, 11: processing apparatus
30, 40: computer
31: execution unit
32, 52: storage unit
50: server
51: analysis unit
310: preprocessing unit
311: feature change calculation unit
312: diagnosis and alarm unit
313: feature calculation unit
314: component deterioration degree calculation unit
510: calculation condition setting unit
511: apparatus common threshold setting unit
512: diagnosis result display unit
520: diagnosis result storage unit
521: maintenance period information storage unit

1. A diagnosis device for a processing apparatus that uses a component in the processing apparatus as a maintenance target, the diagnosis device comprising:
a feature change calculation unit configured to calculate a deterioration degree corresponding to a change index based on a feature of each piece of sensor waveform data of a sensor item corresponding to a plurality of sensors (state sensor group) that measure a state of the component; and
a component deterioration degree calculation unit configured to calculate a component deterioration degree corresponding to the component in a one-to-one manner using a plurality of the deterioration degrees.

2. The diagnosis device for a processing apparatus according to claim 1, further comprising:
a diagnosis and alarm unit configured to perform diagnosis and issue an alarm by comparing an apparatus common threshold set among components in a processing apparatus group with the component deterioration degree.

3. The diagnosis device for a processing apparatus according to claim 1, wherein
the feature change calculation unit uses, as the change index, at least one of a difference between the feature in a diagnosis cycle and a mean value of features in an initial state section (hereinafter referred to as “initial features”) of the component, a ratio of the feature to the mean value of the initial features, or a Mahalanobis distance between the feature and the mean value of the initial features.

4. The diagnosis device for a processing apparatus according to claim 1, wherein
the component deterioration degree calculation unit calculates the component deterioration degree as a continuous probability value by using a method of applying a regression model including a decision tree structure.

5. The diagnosis device for a processing apparatus according to claim 2, further comprising:
an apparatus common threshold setting unit configured to set the apparatus common threshold by comprehensively searching a time-series trend of the component deterioration degree in each component of the processing apparatus group for a prediction accuracy index in a deterioration period.

6. The diagnosis device for a processing apparatus according to claim 5, wherein
the apparatus common threshold setting unit sets the apparatus common threshold using a precision and a recall as the prediction accuracy index such that the precision is equal to or greater than a reference value and the recall is maximum.

7. The diagnosis device for a processing apparatus according to claim 2, further comprising:
a diagnosis result display unit configured to collectively display a time-series trend of the component deterioration degree in each component of the processing apparatus group and contribution degrees of the plurality of deterioration degrees used for calculating the component deterioration degree.

8. A diagnosis system for a processing apparatus that uses a component in the processing apparatus as a maintenance target, the diagnosis system comprising:
a feature change calculation unit configured to calculate a deterioration degree corresponding to a change index based on a feature of each piece of sensor waveform data of a sensor item corresponding to a plurality of sensors (state sensor group) that measure a state of the component; and
a component deterioration degree calculation unit configured to calculate a component deterioration degree corresponding to the component in a one-to-one manner using a plurality of the deterioration degrees.

9. The diagnosis system for a processing apparatus according to claim 8, further comprising:
a diagnosis and alarm unit configured to perform diagnosis and issue an alarm by comparing an apparatus common threshold set among components in a processing apparatus group with the component deterioration degree.

10. A diagnosis method for a processing apparatus that uses a component in the processing apparatus as a maintenance target, the diagnosis method comprising:
a step of calculating, by a feature change calculation unit, a deterioration degree corresponding to a change index based on a feature of each piece of sensor waveform data of a sensor item corresponding to a plurality of sensors (state sensor group) that measure a state of the component; and
a step of calculating, by a component deterioration degree calculation unit, a component deterioration degree corresponding to the component in a one-to-one manner using a plurality of the deterioration degrees.

11. The diagnosis method for a processing apparatus according to claim 10, further comprising:
a step of performing diagnosis and issuing an alarm, by a diagnosis and alarm unit, by comparing an apparatus common threshold set among components in a processing apparatus group with the component deterioration degree.

12. The diagnosis device for a processing apparatus according to claim 2, wherein
the feature change calculation unit uses, as the change index, at least one of a difference between the feature in a diagnosis cycle and a mean value of features in an initial state section (hereinafter referred to as “initial features”) of the component, a ratio of the feature to the mean value of the initial features, or a Mahalanobis distance between the feature and the mean value of the initial features.

13. The diagnosis device for a processing apparatus according to claim 2, wherein
the component deterioration degree calculation unit calculates the component deterioration degree as a continuous probability value by using a method of applying a regression model including a decision tree structure.

14. The diagnosis device for a processing apparatus according to claim 5, further comprising:
a diagnosis result display unit configured to collectively display a time-series trend of the component deterioration degree in each component of the processing apparatus group and contribution degrees of the plurality of deterioration degrees used for calculating the component deterioration degree.

15. The diagnosis device for a processing apparatus according to claim 6, further comprising:
a diagnosis result display unit configured to collectively display a time-series trend of the component deterioration degree in each component of the processing apparatus group and contribution degrees of the plurality of deterioration degrees used for calculating the component deterioration degree.
